(19) United States
(12) Patent Application Publication
(10) Pub. No.: US 2016/0190355 A1
(43) Pub. Date: Jun. 30, 2016

(54) Auto-Adjusting Device and Method for Adjusting Drive Voltage Light Receiver

(71) Applicants: Sintai Optical (Shenzhen) Co., Ltd., Shenzhen City (CN); Asia Optical International Ltd., Tortola (GB)

(72) Inventors: Song Li, Shenzhen City (CN); Qi Lan, Shenzhen City (CN)

(21) Appl. No.: 14/979,893

(22) Filed: Dec. 28, 2015

(30) Foreign Application Priority Data
Dec. 29, 2014 (CN) 201410836124.3

(51) Int. Cl. H01L 31/02

(52) U.S. Cl. CPC H01L 31/02027

(57) ABSTRACT

An auto-adjusting device for adjusting a drive voltage of a light receiver includes an amplifier, an analog-to-digital converter, a determination control circuit and a boost circuit. The amplifier is configured to amplify an analog signal generated by the light receiver. The analog-to-digital converter is configured to convert the amplified analog signal to a digital signal. The determination control circuit is configured to process and determine the digital signal, and output a control signal when the processed digital signal satisfies a predetermined condition. The boost circuit is configured to receive the control signal and adjust the drive voltage of the light receiver.

### BACKGROUND OF THE INVENTION

1. Field of the Invention

The invention relates to an auto-adjusting device and method for adjusting a drive voltage of a light receiver.

2. Description of the Related Art

An avalanche photodiode working under a high gain condition is necessarily provided with a drive voltage near a breakdown point. When an avalanche photodiode of a range finder is driven by a fixed high voltage, the gain of the avalanche photodiode and the magnitude of output signals may vary due to the environmental temperature variations, which may affect the stability and ability of distance measurement of the ranger finder.

### BRIEF SUMMARY OF THE INVENTION

If an avalanche photodiode is required to work at a high temperature, a high drive voltage must be provided for the avalanche photodiode to maintain the high gain condition. Therefore, an auto-adjusting device is needed to prevent the avalanche photodiode from damage due to an over-high drive voltage when the avalanche photodiode works under the high gain condition.

An object of the invention is to provide an auto-adjusting device and method for adjusting a drive voltage of a light receiver. The drive voltage of the light receiver is adjusted in accordance with temperature variations so that the light receiver can be maintained in a stable condition under wide range variation of temperature. Also, the circuit construction of the invention is not complicated, which is advantageous in assembly and manufacturing cost.

The auto-adjusting device for adjusting a drive voltage of a light receiver in accordance with an exemplary embodiment of the invention includes an amplifier, an analog-to-digital converter, a determination control circuit and a boost circuit. The amplifier is configured to amplify an analog signal generated by the light receiver. The analog-to-digital converter is configured to convert the amplified analog signal to a digital signal. The determination control circuit is configured to process and determine the digital signal, and output a control signal when the processed digital signal satisfies a predetermined condition. The boost circuit is configured to receive the control signal and adjust the drive voltage of the light receiver.

In another exemplary embodiment, the predetermined condition includes a preset value, and the processed digital signal satisfies the predetermined condition when the processed digital signal is less than or equal to the preset value.

In yet another exemplary embodiment, the determination control circuit stops outputting the control signal when the processed digital signal does not satisfy the predetermined condition.

In another exemplary embodiment, the predetermined condition includes a preset value, and the processed digital signal does not satisfy the predetermined condition when the processed digital signal is greater than the preset value.

In yet another exemplary embodiment, the control signal includes a pulse width modulation (PWM) signal.

In another exemplary embodiment, the determination control circuit includes a field programmable gate array (FPGA).

In yet another exemplary embodiment, the light receiver includes an avalanche photodiode (APD).

In another exemplary embodiment, the analog signal generated by the light receiver is sampled by the analog-to-digital converter to obtain the digital signal; the determination control circuit processes the digital signal and determines whether the processed digital signal satisfies the predetermined condition; and the boost circuit adjusts the drive voltage of the light receiver when the processed signal satisfies the predetermined condition.

The method for auto-adjusting a drive voltage of a light receiver in accordance with an exemplary embodiment of the invention includes the steps of sampling an analog signal generated by a light receiver to obtain a digital signal; processing the digital signal; determining whether the processed digital signal satisfies a predetermined condition; and adjusting the drive voltage of the light receiver when the processed signal satisfies the predetermined condition.

In another exemplary embodiment, the predetermined condition includes a preset value, and the processed digital signal satisfies the predetermined condition when the processed digital signal is less than or equal to the preset value.

In yet another exemplary embodiment, the method further includes the step of stopping adjusting the drive voltage of the light receiver when the processed digital signal does not satisfy the predetermined condition.

In another exemplary embodiment, the predetermined condition includes a preset value, and the processed digital signal does not satisfy the predetermined condition when the processed digital signal is greater than the preset value.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a block diagram of an auto-adjusting device for adjusting a drive voltage of a light receiver in accordance with the invention; and

FIG. 2 is a flow chart of a method for auto-adjusting a drive voltage of a light receiver in accordance with the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

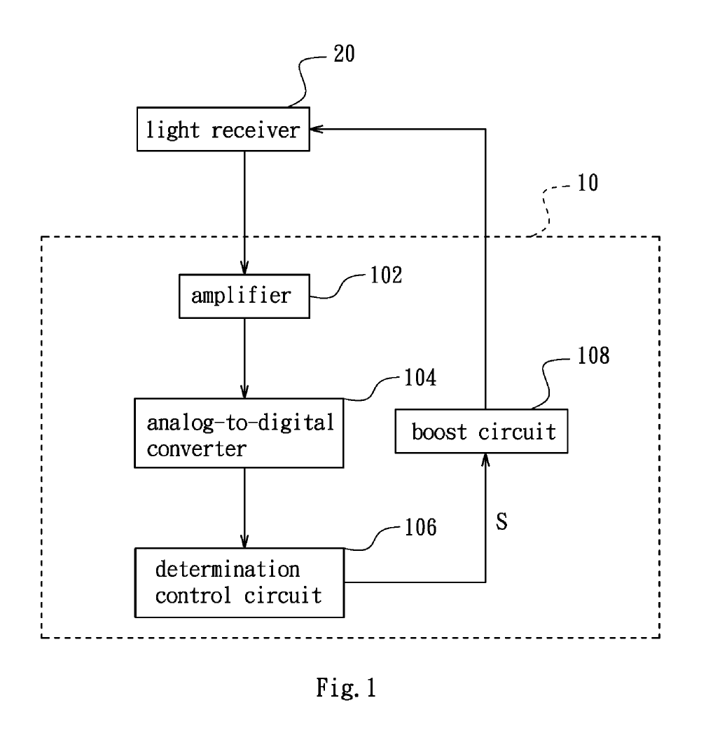

Referring to FIG. 1, an auto-adjusting device 10 of the invention is coupled to a light receiver 20 to automatically adjust the drive voltage of the light receiver 20 so that the light receiver 20 can work under a high gain condition without being affected by temperature. In this embodiment, the light receiver 20 is an avalanche photodiode (APD).

The auto-adjusting device 10 of the invention includes an amplifier 102, an analog-to-digital converter (ADC) 104, a determination control circuit 106 and a boost circuit 108. In operation, the light receiver 20 receives light and generates photocurrent which is an analog signal. The analog signal is amplified by the amplifier 102 and converted to a digital signal by the analog-to-digital converter 104. The digital signal is processed by the determination control circuit 106. The determination control circuit 106 also determines whether the digital signal satisfies a predetermined condition. When the digital signal satisfies the predetermined condition, the determination control circuit 106 generates a control signal S. The boost circuit 108 adjusts the drive voltage of the light receiver 20 when the boost circuit 108 receives the control signal S.

In this embodiment, the determination control circuit 106 is a field programmable gate array (FPGA).

In this embodiment, the control signal S is a pulse width modulation (PWM) signal.

In this embodiment, the predetermined condition includes a preset value, and the digital signal is compared with the preset value. When the digital signal is less than or equal to the predetermined condition, it is determined that the digital signal satisfies the predetermined condition, and the determination control circuit 106 outputs the control signal S to adjust the drive voltage of the light receiver 20. On the contrary, when the digital signal is greater than the preset value, it is determined that the digital signal does not satisfy the predetermined condition, and the determination control circuit 106 stops outputting the control signal S.

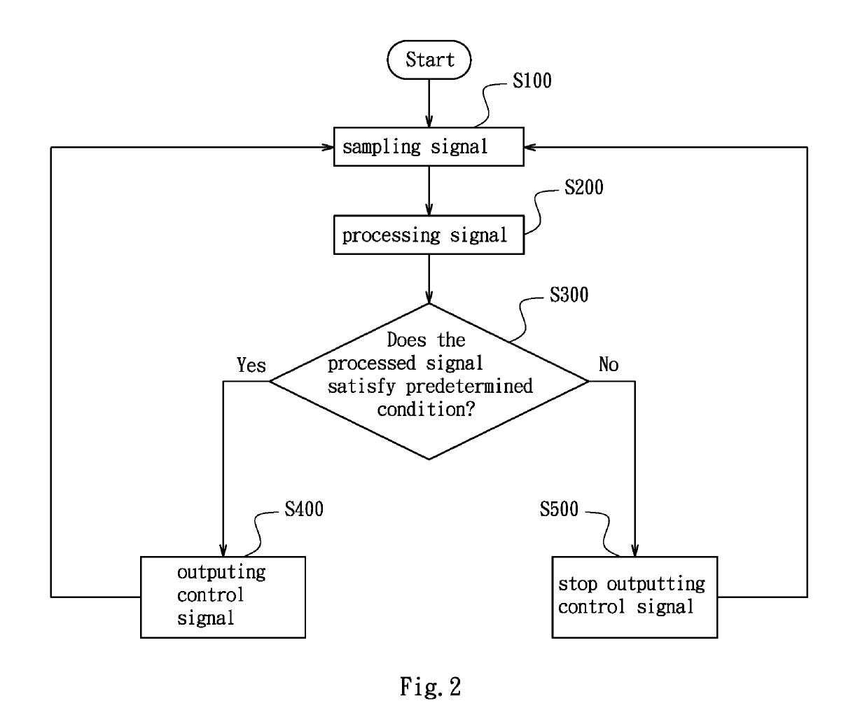

Referring to FIG. 2, an auto-adjusting method for adjusting a drive voltage of the light receiver of the invention is shown. In step S100, an analog signal generated by the light receiver 20 is sampled, through signal amplification and conversion, to obtain a digital signal. In step S200, the digital signal is processed for the subsequent determination. In step S300, it is determined whether the digital signal satisfies a predetermined condition. When the digital signal satisfies the predetermined condition, the procedure enters step S400, wherein a control signal S is output, and the control signal S is received by the boost circuit 108 to adjust the drive voltage of the light receiver 20. On the contrary, when the digital signal does not satisfy the predetermined condition, the procedure enters step S500, wherein the output of the control signal is stopped.

The auto-adjusting device of the invention is capable of maintaining the light receiver in a stable condition under wide range variation of temperature. The analog-to-digital converter (ADC) 104 and the determination control circuit 106 have low cost and simple construction, which is advantageous in assembly and manufacturing cost.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An auto-adjusting device for adjusting a drive voltage of a light receiver, comprising:
an amplifier configured to amplify an analog signal generated by the light receiver;
an analog-to-digital converter configured to convert the amplified analog signal to a digital signal;
a determination control circuit configured to process and determine the digital signal, and output a control signal when the processed digital signal satisfies a predetermined condition; and
a boost circuit configured to receive the control signal and adjust the drive voltage of the light receiver.

2. The auto-adjusting device as claimed in claim 1, wherein the predetermined condition comprises a preset value, and the processed digital signal satisfies the predetermined condition when the processed digital signal is less than or equal to the preset value.

3. The auto-adjusting device as claimed in claim 1, wherein the determination control circuit stops outputting the control signal when the processed digital signal does not satisfy the predetermined condition.

4. The auto-adjusting device as claimed in claim 3, wherein the predetermined condition comprises a preset value, and the processed digital signal does not satisfy the predetermined condition when the processed digital signal is greater than the preset value.

5. The auto-adjusting device as claimed in claim 1, wherein the control signal comprises a pulse width modulation (PWM) signal.

6. The auto-adjusting device as claimed in claim 1, wherein the determination control circuit comprises a field programmable gate array (FPGA).

7. The auto-adjusting device as claimed in claim 1, wherein the light receiver comprises an avalanche photodiode (APD).

8. The auto-adjusting device as claimed in claim 1, wherein the analog signal generated by the light receiver is sampled by the analog-to-digital converter to obtain the digital signal; the determination control circuit processes the digital signal and determines whether the processed digital signal satisfies the predetermined condition; and the boost circuit adjusts the drive voltage of the light receiver when the processed signal satisfies the predetermined condition.

9. The auto-adjusting device as claimed in claim 8, wherein the predetermined condition comprises a preset value, and the processed digital signal satisfies the predetermined condition when the processed digital signal is less than or equal to the preset value.

10. The auto-adjusting device as claimed in claim 8, wherein the determination control circuit stops outputting the control signal when the processed digital signal does not satisfy the predetermined condition.

11. The auto-adjusting device as claimed in claim 10, wherein the predetermined condition comprises a preset value, and the processed digital signal does not satisfy the predetermined condition when the processed digital signal is greater than the preset value.

12. The auto-adjusting device as claimed in claim 8, wherein the control signal comprises a pulse width modulation (PWM) signal.

13. The auto-adjusting device as claimed in claim 8, wherein the determination control circuit comprises a field programmable gate array (FPGA).

14. The auto-adjusting device as claimed in claim 8, wherein the light receiver comprises an avalanche photodiode (APD).

15. An auto-adjusting method for adjusting a drive voltage of a light receiver, comprising:
sampling an analog signal generated by a light receiver to obtain a digital signal;
processing the digital signal;
determining whether the processed digital signal satisfies a predetermined condition; and
adjusting the drive voltage of the light receiver when the processed signal satisfies the predetermined condition.

16. The auto-adjusting method as claimed in claim 15, wherein the predetermined condition comprises a preset value, and the processed digital signal satisfies the predetermined condition when the processed digital signal is less than or equal to the preset value.

17. The auto-adjusting method as claimed in claim 15, further comprising stopping adjusting the drive voltage of the light receiver when the processed digital signal does not satisfy the predetermined condition.

18. The auto-adjusting method as claimed in claim 17, wherein the predetermined condition comprises a preset value, and the processed digital signal does not satisfy the predetermined condition when the processed digital signal is greater than the preset value.
